(19) United States
(12) Patent Application Publication
(10) Pub. No.: US 2006/0179389 A1
(43) Pub. Date: Aug. 10, 2006

(54) Method and apparatus for automatically controlling audio volume

(75) Inventors: Chul-woo Lee, Suwon-si (KR); Geon-hyoung Lee, Hwaseong-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/288,072

(22) Filed: Nov. 29, 2005

(30) Foreign Application Priority Data
Feb. 4, 2005 (KR) 10-2005-0010756

(51) Int. Cl. H04L 1/00; H03M 13/00; G08C 25/00; G06F 11/00; G06F 11/30

(52) U.S. Cl. 714/746

(57) ABSTRACT

A method and apparatus are provided for solving a noise problem of data output from a digital audio decoder. A volume control method includes detecting errors from data; and controlling an output volume of the data based on a number of the errors. Accordingly, by controlling the output volume of audio data based on the number of errors generated from the audio data, sound that is not unpleasant for listeners can be provided.

### CROSS-REFERENCE TO RELATED PATENT APPLICATION

This application priority from Korean Patent Application No. 10-2005-0010756, filed on Feb. 4, 2005, in the Korean Intellectual Property Office, the disclosure of which is incorporated herein in its entirety by reference.

### BACKGROUND OF THE INVENTION

1. Field of the Invention

Apparatuses and methods consistent with the present invention relate to solving a noise problem of data output from a digital audio decoder, and more particularly, to solving a noise problem specific to a signal output from a digital audio decoder.

2. Description of the Related Art

Accompanying the development of digital technology, digital audio broadcasting has been developed as a new transmission system to overcome the disadvantages of analog audio broadcasting. However, noise that is usually not generated in analog audio broadcasting is generated in digital audio broadcasting. When the transmission environment is bad, whereas an analog audio signal does not change much although noise is added to it, a digital audio signal turns into a completely different signal even if only a few bits of the original audio signal are changed due to noise since the digital audio signal is a compressed signal.

To solve the noise problem specific to digital signals, a plurality of methods have been suggested. Examples of these methods include methods of muting an error-generated portion and methods of repeatedly outputting a non-error portion when the number of error-generated portions is more than a predetermined number. However, these conventional methods are unpleasant for listeners and generate harsh pop noise by repeatedly outputting the non-error portion and by muting the error-generated portion, respectively.

### SUMMARY OF THE INVENTION

The present invention provides methods and apparatuses that can solve noise problems specific to digital signals which neither generate pop noise harsh to listeners nor are unpleasant for listeners.

The present invention also provides a computer readable recording medium having recorded thereon a computer readable program for performing the method.

According to an aspect of the present invention, there is provided a volume control method comprising: detecting errors from data; and controlling an output volume of the data based on a number of the errors.

According to another aspect of the present invention, there is provided a volume control apparatus comprising: an error detector detecting errors from data; and a volume controller controlling an output volume of the data based on a number of the errors.

According to another aspect of the present invention, there is provided a computer readable recording medium having recorded thereon a computer readable program for performing the volume control method.

According to another aspect of the present invention, there is provided a two-channel volume control method comprising: detecting first channel error frames from a plurality of first channel frames and detecting second channel error frames from a plurality of second channel frames; controlling an output volume of the first channel frames based on a number of the first channel error frames; and controlling an output volume of the second channel frames based on a number of the second channel error frames.

According to another aspect of the present invention, there is provided a wireless signal volume control method comprising: extracting a predetermined wireless signal from wireless signals; demodulating the extracted predetermined wireless signal; decoding the demodulated signal; detecting errors from decoded data; and controlling an output volume of the data based on a number of the errors.

According to another aspect of the present invention, there is provided a wired signal volume control method comprising: receiving a wired signal from an external network; extracting a predetermined bitstream from the received wired signal; decoding the extracted bitstream; detecting errors from decoded data; and controlling an output volume of the data based on a number of the errors.

### BRIEF DESCRIPTION OF THE DRAWINGS

The above and other aspects of the present invention will become more apparent by describing in detail exemplary embodiments thereof with reference to the attached drawings in which:

FIG. 1 is a block diagram of a volume control apparatus according to an exemplary embodiment of the present invention;

FIG. 2 is a diagram of a threshold table according to an exemplary embodiment of the present invention;

FIG. 3 is a block diagram of a two-channel audio output apparatus according to an exemplary embodiment of the present invention;

FIG. 4 is a block diagram of an audio output apparatus in a wireless environment according to an exemplary embodiment of the present invention;

FIG. 5 is a block diagram of an audio output apparatus in a wired environment according to an exemplary embodiment of the present invention;

FIG. 6 is a flowchart illustrating a volume control method according to an exemplary embodiment of the present invention;

FIG. 7 is a flowchart illustrating a two-channel audio output method according to an exemplary embodiment of the present invention;

FIG. 8 is a flowchart illustrating an audio output method in a wireless environment according to an exemplary embodiment of the present invention; and

FIG. 9 is a flowchart illustrating an audio output method in a wired environment according to an exemplary embodiment of the present invention.

### DETAILED DESCRIPTION OF EXEMPLARY EMBODIMENTS OF THE INVENTION

Hereinafter, exemplary embodiments of the present invention will now be described in detail with reference to the accompanying drawings.

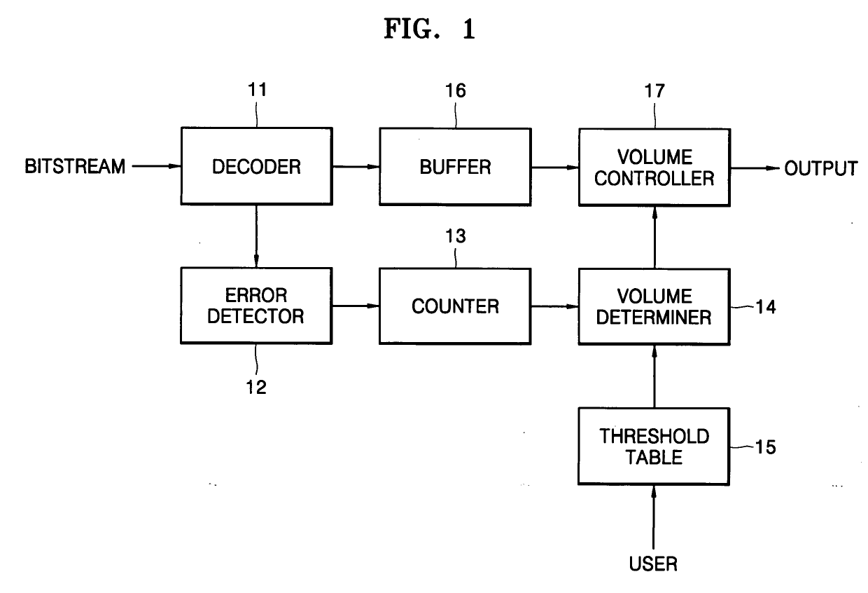

FIG. 1 is a block diagram of a volume control apparatus according to an exemplary embodiment of the present invention.

Referring to FIG. 1, the volume control apparatus includes a decoder 11, an error detector 12, a counter 13, a volume determiner 14, a threshold table 15, a buffer 16, and a volume controller 17.

The decoder 11 decodes a bitstream based on the same audio format standard as that used by an audio contents provider. Such audio format standards are Moving Picture Experts Group (MPEG)-1 layer 2 and MPEG-2 layer 2 used in digital audio broadcasting (DAB), bit-sliced arithmetic coding (BSAC) used in terrestrial DAB, advance audio coding (AAC) used in satellite DAB, and audio code number 3 (AC-3) used in high definition television (HDTV) broadcasting.

The error detector 12 detects errors from pulse-coded modulation (PCM) data, into which the bitstream is decoded by the decoder 11. The PCM data includes a plurality of frames forming audio contents, the decoder 11 outputs the decoded results in frame units, and the error detector 12 detects error frames from the plurality of frames. In the present exemplary embodiment, the error detector 12 detects errors from the PCM data using error detection methods such as cyclic redundancy check (CRC) and checksum.

The counter 13 counts the number of the error frames detected by the error detector 12 from frames that make up an error detection unit. If the error detection unit is 24 frames, the counter 13 counts the number of the error frames detected by the error detector 12 from the latest 24 frames.

The volume determiner 14 determines a volume level corresponding to a threshold range to which the value counted by the counter 13 belongs with reference to the threshold table 15 in which error count thresholds and volume levels corresponding to each other are stored.

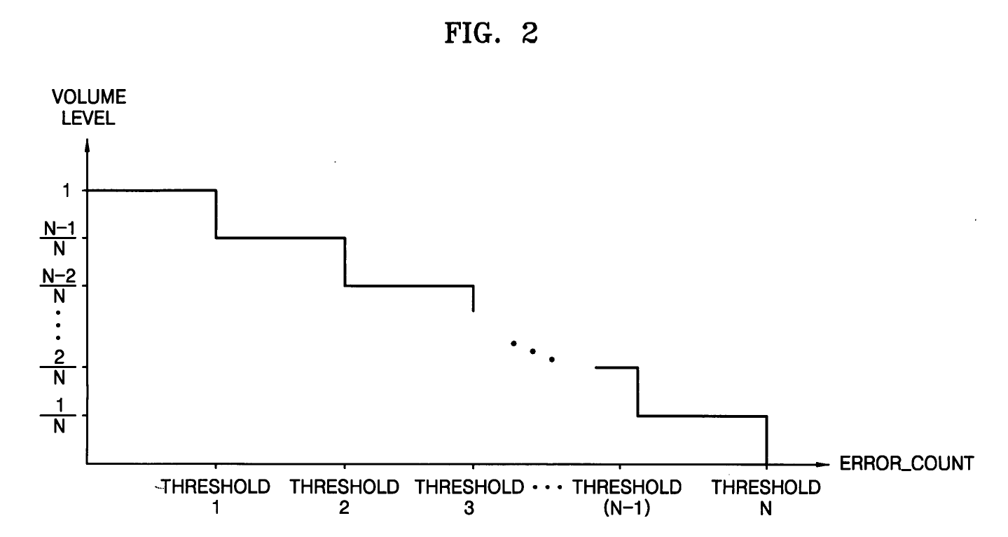

FIG. 2 is a diagram illustrating the threshold table 15 according to an exemplary embodiment of the present invention.

Referring to FIG. 2, the horizontal axis of the threshold table 15 indicates an error count value, and the vertical axis indicates a volume level. In particular, the horizontal axis is divided into N thresholds, and the vertical axis is divided into N volume levels, wherein the N thresholds and the N volume levels correspond to each other, respectively.

In detail, an error count value belonging to a range below a first threshold, threshold 1, corresponds to a volume level 1, an error count value belonging to a range above the first threshold, threshold 1, below a second threshold, threshold 2, corresponds to a volume level (N-1)/N, . . . , and an error count value belonging to a range above an N^{th} threshold corresponds to a volume level 0.

That is, the volume determiner 14 determines the volume level 1 if the value counted by the counter 13 belongs to the range below the first threshold, threshold 1, the volume level (N-1)/N if the value counted by the counter 13 belongs to the range above the first threshold, threshold 1, and below the second threshold, threshold 2, . . . , and the volume level 0 if the value counted by the counter 13 belongs to the range above the N^{th} threshold by referring to the threshold table 15 shown in FIG. 2. In the present exemplary embodiment, the thresholds on the horizontal axis are not fixed values. That is, they can be user-determined. Thus, the user can hear a sound of suitable volume by freely setting the thresholds in accordance with the listening environment or the user's taste.

The buffer 16 temporarily stores and outputs the PCM data in order to match a data output speed of the decoder 11 with a data processing speed of a device (not shown in FIG. 1) that processes data output from the volume control apparatus.

The volume controller 17 controls a volume of the PCM data output from the buffer 16 in accordance with the volume level determined by the volume determiner 14. In more detail, the volume controller 17 controls the volume of the PCM data output from the buffer 16 by multiplying the magnitude of the PCM data output from the buffer 16 by the volume level determined by the volume determiner 14. That is, the volume controller 17 controls the volume of the PCM data to be inversely proportional to the number of errors detected by the error detector 12.

For example, it is assumed that the horizontal axis of the threshold table 15 is divided into 4 thresholds, the vertical axis is divided into 4 volume levels, the counter 13 counts the number of error frames detected by the error detector 12 from 24 frames, and the user sets a first threshold, a second threshold, a third threshold and a fourth threshold to 4, 8, 12 and 16, respectively.

If the number of error frames counted by the counter 13 is 6, since value is in a range between the first threshold and the second threshold, the volume determiner 14 determines the volume level to be (4-1)/4=¾ by referring to the threshold table 15. Then, the volume controller 17 lowers the volume of the PCM data by ¾ by multiplying the magnitude of the PCM data output from the buffer 16 by ¾.

If the number of error frames counted by the counter 13 is less than 4 due to an improved transmission environment, since this value is in a range below the first threshold, the volume determiner 14 determines the volume level to be 1 by referring to the threshold table 15. Then, the volume controller 17 outputs the volume of the PCM data as it is unchanged because the magnitude of the PCM data output from the buffer 16 is multiplied by 1.

If the number of error frames counted by the counter 13 is greater than 8 due to a poorer transmission environment, since this value is in a range between the second threshold and the third threshold, the volume determiner 14 determines the volume level to be (4-2)/4=½ by referring to the threshold table 15. Then, the volume controller 17 lowers the volume of the PCM data by ½ by multiplying the magnitude of the PCM data output from the buffer 16 by ½.

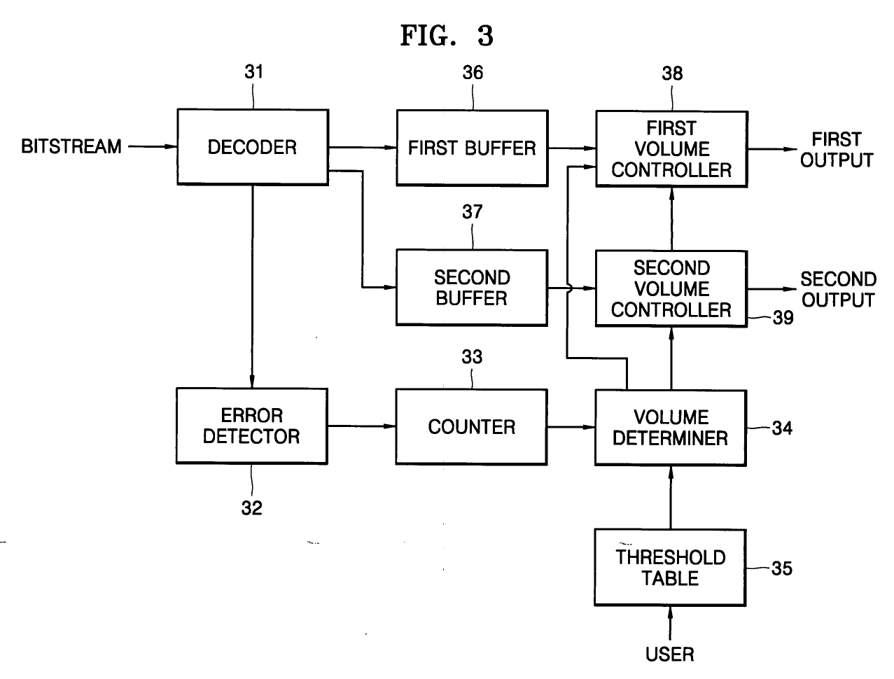

FIG. 3 is a block diagram of a two-channel audio output apparatus according to an exemplary embodiment of the present invention.

Referring to FIG. 3, the two-channel audio output apparatus includes a decoder 31, an error detector 32, a counter 33, a volume determiner 34, a threshold table 35, a first buffer 36, a second buffer 37, a first volume controller 38 and a second volume controller 39. The two-channel audio output apparatus shown in FIG. 3 is designed based on the volume control apparatus shown in FIG. 1. Therefore, a detailed explanation of the two-channel audio output apparatus according to the present exemplary embodiment is omitted.

The decoder 31 decodes a bitstream based on the same audio format standard as that used by an audio contents provider.

The bitstream is decoded into PCM data by the decoder 31, and the error detector 32 detects errors from the PCM data. The PCM data includes a plurality of first channel frames and a plurality of second channel frames forming two-channel audio contents. The error detector 32 detects first channel error frames from the plurality of first channel frames and second channel error frames from the plurality of second channel frames.

The counter 33 counts the number of first channel error frames and the number of second channel error frames, both of which are detected by the error detector 32, from frames corresponding to the error detection unit.

The volume determiner 34 determines a first channel volume level corresponding to a threshold range to which the number of the first channel error frames counted by the counter 33 belongs and a second channel volume level corresponding to a threshold range to which the number of the second channel error frames counted by the counter 33 belongs with reference to the threshold table 35 in which error count thresholds and volume levels corresponding to each other are stored.

The first buffer 36 temporarily stores and outputs the first channel frames of the PCM data decoded by the decoder 31 in order to match a data output speed of the decoder 31 with a data processing speed of a device (not shown in FIG. 3) that processes data output from the two-channel audio output apparatus.

The second buffer 37 temporarily stores and outputs the second channel frames of the PCM data decoded by the decoder 31 in order to match a data output speed of the decoder 31 with the data processing speed of the device that processes data output from the two-channel audio output apparatus.

The first volume controller 38 controls a volume of the first channel frames output from the first buffer 36 according to the first channel volume level determined by the volume determiner 34. In more detail, the first volume controller 38 controls the volume of the first channel frames output from the first buffer 36 by multiplying the data magnitude of the first channel frames output from the first buffer 36 by the volume level determined by the volume determiner 34. That is, the volume of the first channel frames is inversely proportional to the number of first channel error frames detected by the error detector 32.

The second volume controller 39 controls a volume of the second channel frames output from the second buffer 37 according to the second channel volume level determined by the volume determiner 34. In more detail, the second volume controller 39 controls the volume of the second channel frames output from the second buffer 37 by multiplying the data magnitude of the second channel frames output from the second buffer 37 by the volume level determined by the volume determiner 34. That is, the volume of the second channel frames is inversely proportional to the number of second channel error frames detected by the error detector 32.

It will be understood by those of ordinary skill in the art that a 2.1 channel audio output apparatus, a 5.1 channel audio output apparatus and a greater than 5.1 channel audio output apparatus can be easily designed based on the two-channel audio output apparatus illustrated in FIG. 3.

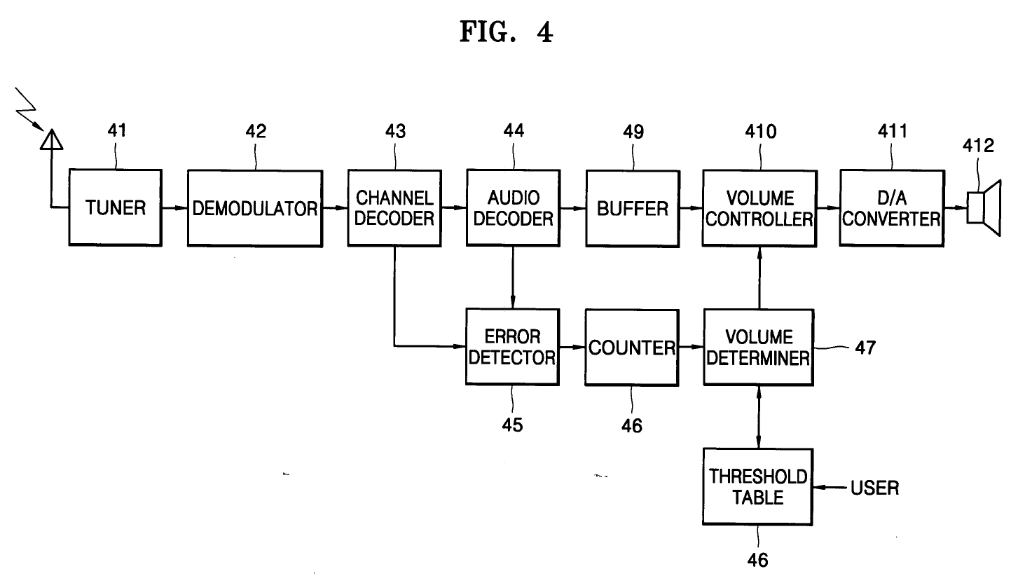

FIG. 4 is a block diagram of an audio output apparatus in a wireless environment according to an exemplary embodiment of the present invention.

Referring to FIG. 4, the wireless audio output apparatus includes a tuner 41, a demodulator 42, a channel decoder 43, an audio decoder 44, an error detector 45, a counter 46, a volume determiner 47, a threshold table 48, a buffer 49, a volume controller 410, a digital-to-analog (D/A) converter 411 and a speaker 412. The wireless audio output apparatus illustrated in FIG. 4 is designed based on the volume control apparatus illustrated in FIG. 1. Therefore, a detailed explanation of the wireless audio output apparatus according to the present exemplary embodiment is omitted.

The tuner 41 extracts only a wireless signal corresponding to a frequency selected by a user or a system among wireless signals received through an antenna.

The demodulator 42 demodulates the wireless signal extracted by the tuner 41 based on a demodulation method corresponding to a modulation method used by an audio contents provider. An orthogonal frequency division multiplexing (OFDM) method is a modulation/demodulation method generally used for DAB.

The channel decoder 43 generates a bitstream corresponding to a channel selected by the user or the system by channel-decoding the signal demodulated by the demodulator 42.

The bitstream generated by the channel decoder 43 is decoded into PCM data by the audio decoder 44 based on the same audio format standard as that used by the audio contents provider, and the error detector 45 detects errors from PCM data.

The counter 46 counts the number of error frames detected by the error detector 45 from frames that make up an error detection unit.

The volume determiner 47 determines a volume level corresponding to a threshold range to which the value counted by the counter 46 belongs with reference to the threshold table 48 in which error count thresholds and volume levels corresponding to each other are stored.

The buffer 49 temporarily stores and outputs the PCM data decoded by the audio decoder 44 in order to match a data output speed of the audio decoder 44 with a data processing speed of a device (not shown in FIG. 4) that processes data output from the audio output apparatus in a wireless environment.

The volume controller 410 controls a volume of the PCM data output from the buffer 49 according to the volume level determined by the volume determiner 47.

The D/A converter 411 converts the PCM data having the volume controlled by the volume controller 410 to a user-audible analog signal and outputs the analog signal to the speaker 412.

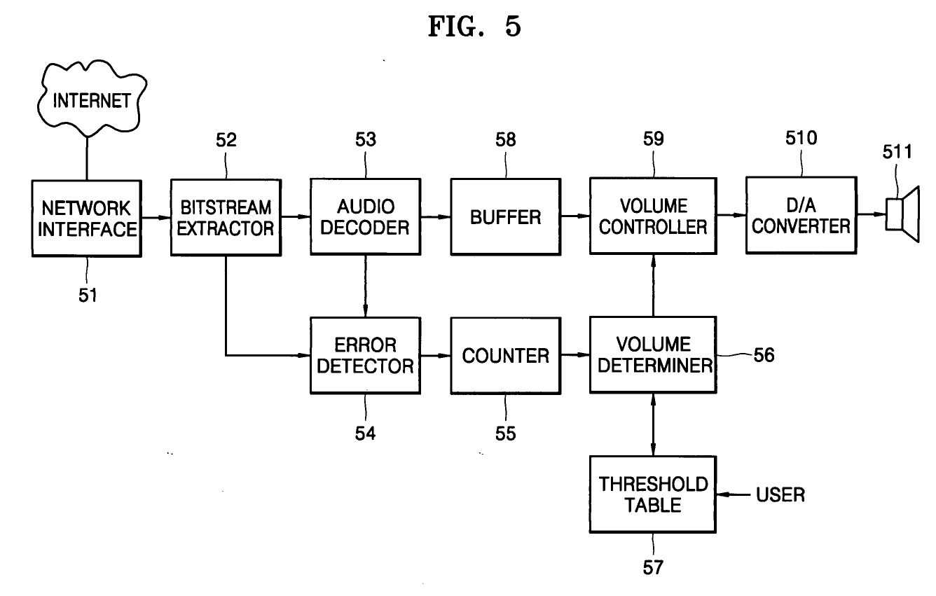

FIG. 5 is a block diagram of an audio output apparatus in a wired environment according to an exemplary embodiment of the present invention.

Referring to FIG. 5, the wired audio output apparatus includes a network interface 51, a bitstream extractor 52, an audio decoder 53, an error detector 54, a counter 55, a volume determiner 56, a threshold table 57, a buffer 58, a volume controller 59, a D/A converter 510 and a speaker 511. The wired audio output apparatus shown in FIG. 5 is designed based on the volume control apparatus shown in FIG. 1. Therefore, a detailed explanation of the wired audio output apparatus according to the present exemplary embodiment is omitted.

The network interface 51 receives a wired signal from an external network such as the Internet.

The bitstream extractor 52 extracts a bitstream corresponding to audio contents from the wired signal received by the network interface 51.

The audio decoder 53 decodes the bitstream extracted by the bitstream extractor 52 into PCM data based on the same audio format standard as that used by an audio contents provider, and the error detector 54 detects errors from the PCM data.

The counter 55 counts the number of error frames detected by the error detector 54 from frames that make up an error detection unit.

The volume determiner 56 determines a volume level corresponding to a threshold range to which the value counted by the counter 55 belongs with reference to the threshold table 57 in which error count thresholds and volume levels corresponding to each other are stored.

The buffer 58 temporarily stores and outputs the PCM data decoded by the audio decoder 53 in order to match a data output speed of the audio decoder 53 with a data processing speed of a device (not shown in FIG. 5) that processes data output from the audio output apparatus in the wired environment.

The volume controller 59 controls a volume of the PCM data output from the buffer 58 according to the volume level determined by the volume determiner 56.

The D/A converter 510 converts the PCM data having the volume controlled by the volume controller 59 to a user-audible analog signal and outputs the analog signal to the speaker 511.

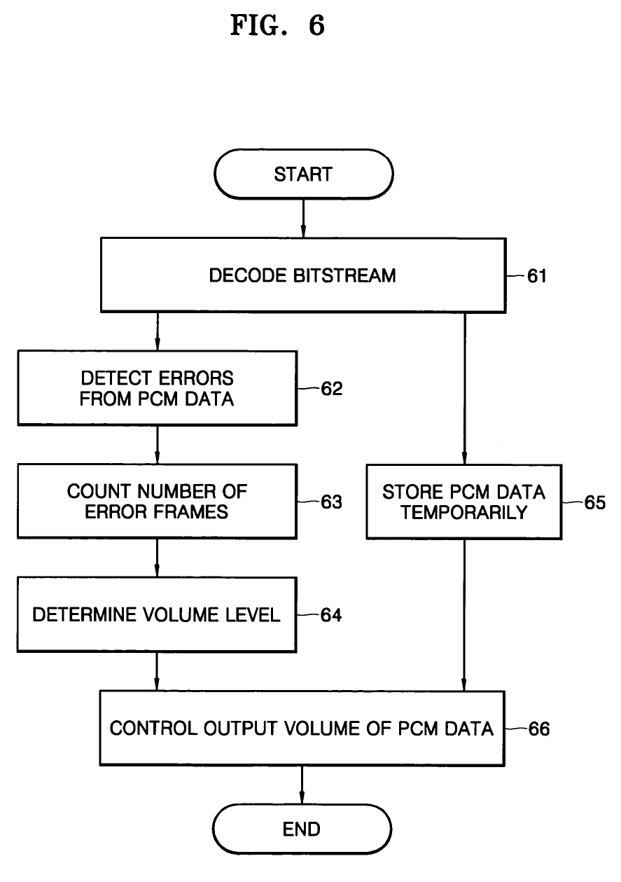

FIG. 6 is a flowchart illustrating a volume control method according to an exemplary embodiment of the present invention.

Referring to FIG. 6, the volume control method according to the present exemplary embodiment includes a series of operations processed by the volume control apparatus illustrated in FIG. 1. Therefore, a detailed explanation of the volume control method according to the present exemplary embodiment is omitted.

In operation 61, the volume control apparatus decodes a bitstream into PCM data based on the same audio format standard as that used by an audio contents provider.

In operation 62, the volume control apparatus detects errors from the PCM data in operation 61.

In operation 63, the volume control apparatus counts the number of error frames detected in operation 62 from frames that make up an error detection unit.

In operation 64, the volume control apparatus determines a volume level corresponding to a threshold range to which the value counted in operation 63 belongs with reference to the threshold table 15 in which error count thresholds and volume levels corresponding to each other are stored.

In operation 65, the volume control apparatus temporarily stores and outputs the PCM data obtained in, operation 61 in order to match a data output speed of the volume control apparatus with a data processing speed of the device that processes data output from the volume control apparatus.

In operation 66, the volume control apparatus controls a volume of the PCM data output in operation 65 according to the volume level determined in operation 64.

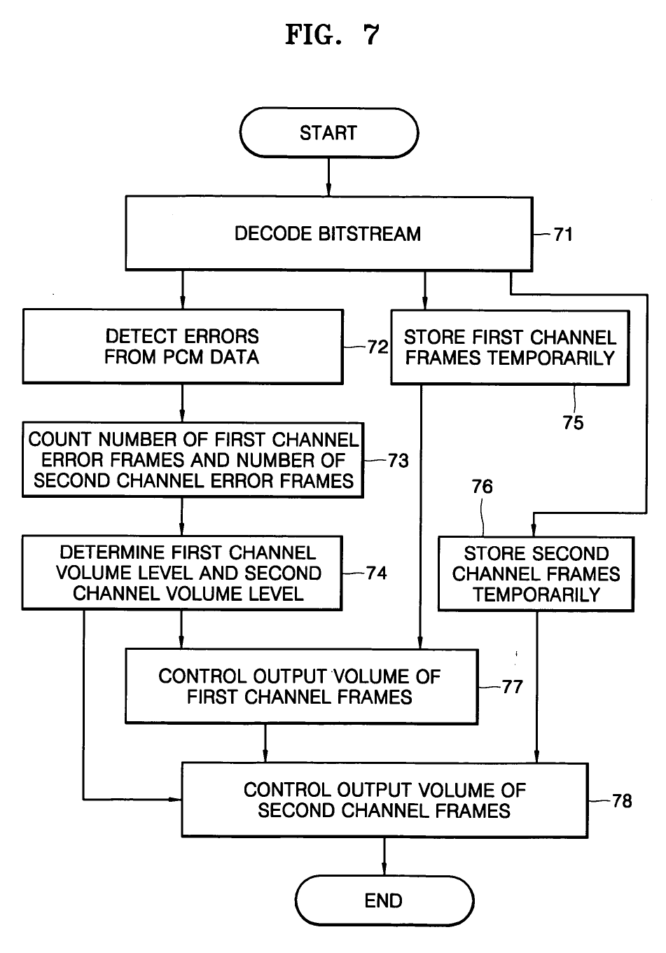

FIG. 7 is a flowchart illustrating a two-channel audio output method according to an exemplary embodiment of the present invention.

Referring to FIG. 7, the two-channel audio output method according to the present exemplary embodiment includes a series of operations processed by the two-channel audio output apparatus illustrated in FIG. 3. Therefore, a detailed explanation of the two-channel audio output method according to the present exemplary embodiment is omitted.

In operation 71, the two-channel audio output apparatus decodes a bitstream into PCM data based on the same audio format standard as that used by an audio contents provider.

In operation 72, the two-channel audio output apparatus detects errors from the PCM data obtained in operation 71.

In operation 73, the two-channel audio output apparatus counts the number of first channel error frames and the number of second channel error frames, both of which are detected in operation 72, from frames that make up an error detection unit.

In operation 74, the two-channel audio output apparatus determines a first channel volume level corresponding to a threshold range to which the number of the first channel error frames counted in operation 73 belongs, and a second channel volume level corresponding to a threshold range to which the number of the second channel error frames counted in operation 73 belongs, with reference to the threshold table 35 in which error count thresholds and volume levels corresponding to each other are stored.

In operation 75, the two-channel audio output apparatus temporarily stores and outputs first channel frames of the PCM data obtained in operation 71 in order to match an output speed of first channel audio data of the two-channel audio output apparatus with a data processing speed of the device that processes data output from the two-channel audio output apparatus.

In operation 76, the two-channel audio output apparatus temporarily stores and outputs second channel frames of the PCM data obtained in operation 71 in order to match an output speed of second channel audio data of the two-channel audio output apparatus with the data processing speed of the device that processes data output from the two-channel audio output apparatus.

In operation 77, the two-channel audio output apparatus controls a volume of the first channel frames output in operation 75 according to the first channel volume level determined in operation 74.

In operation 78, the two-channel audio output apparatus controls a volume of the second channel frames output in operation 76 according to the second channel volume level determined in operation 74.

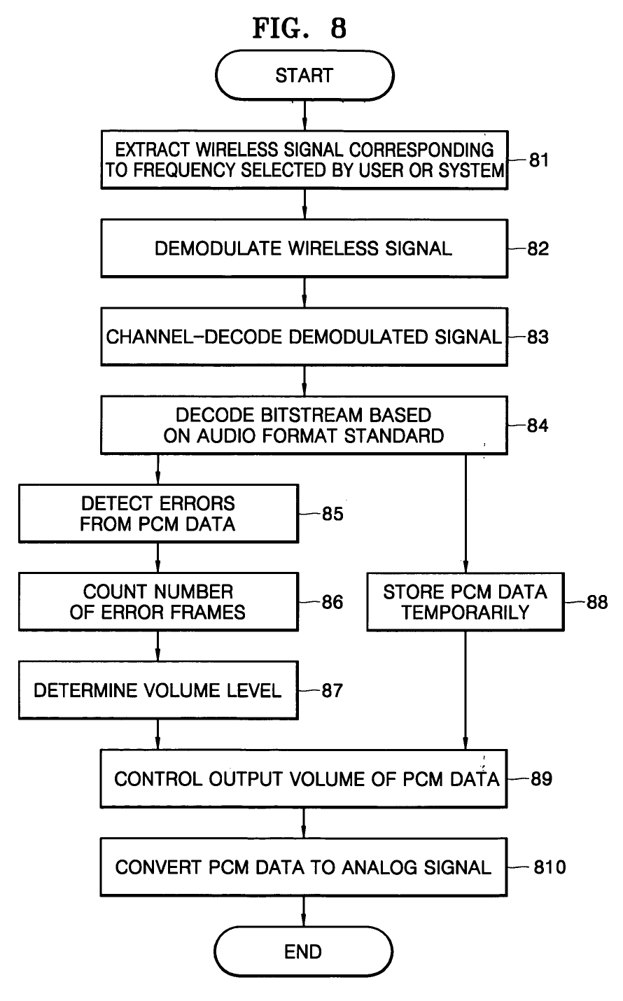

FIG. 8 is a flowchart illustrating an audio output method in a wireless environment according to an exemplary embodiment of the present invention.

Referring to FIG. 8, the wireless audio output method according to the present exemplary embodiment includes a series of operations processed by the wireless audio output apparatus illustrated in FIG. 4. Therefore, a detailed explanation of the wireless audio output method according to the present exemplary embodiment is omitted.

In operation 81, the wireless audio output apparatus extracts only a wireless signal corresponding to a frequency selected by a user or a system among wireless signals received through an antenna.

In operation 82, the wireless audio output apparatus demodulates the wireless signal extracted in operation 81 based on a demodulation method corresponding to a modulation method used by an audio contents provider.

In operation 83, the wireless audio output apparatus generates a bitstream corresponding to a channel selected by the user or the system by channel-decoding the signal demodulated in operation 82.

In operation 84, the wireless audio output apparatus decodes the bitstream obtained in operation 83 into PCM data based on the same audio format standard as that used by the audio contents provider.

In operation 85, the wireless audio output apparatus detects errors from the PCM data obtained in operation 84.

In operation 86, the wireless audio output apparatus counts the number of error frames detected in operation 85 from frames that make up an error detection unit.

In operation 87, the wireless audio output apparatus determines a volume level corresponding to a threshold range to which the value counted in operation 86 belongs with reference to the threshold table 48 in which error count thresholds and volume levels corresponding to each other are stored.

In operation 88, the wireless audio output apparatus temporarily stores and outputs the PCM data obtained in operation 84 in order to match a data output speed of the wireless audio output apparatus with a data processing speed of the device that processes data output from the wireless audio output apparatus.

In operation 89, the wireless audio output apparatus controls a volume of the PCM data output in operation 88 according to the volume level determined in operation 87.

In operation 810, the wireless audio output apparatus converts the PCM data of operation 89 to a user-audible analog signal and outputs the analog signal to the speaker 412.

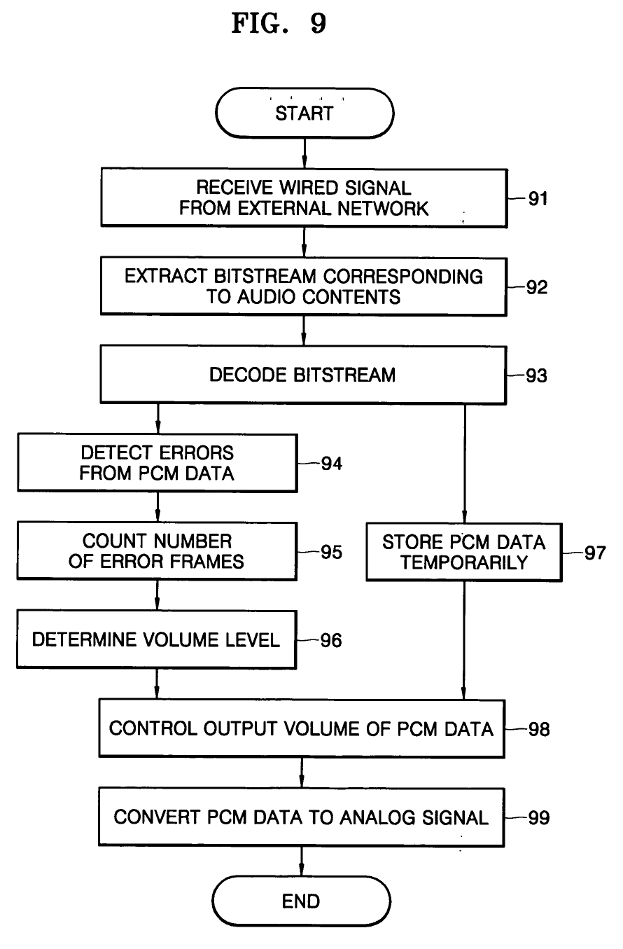

FIG. 9 is a flowchart illustrating an audio output method in a wired environment according to an exemplary embodiment of the present invention.

Referring to FIG. 9, the wired audio output method according to the present exemplary embodiment includes a series of operations processed by the wired audio output apparatus illustrated in FIG. 5. Therefore, a detailed explanation of the wired audio output method according to the present exemplary embodiment is omitted.

In operation 91, the wired audio output apparatus receives a wired signal from an external network such as the Internet.

In operation 92, the wired audio output apparatus extracts a bitstream of audio data from the wired signal received in operation 91.

In operation 93, the wired audio output apparatus decodes the bitstream extracted in operation 92 into PCM data based on the same audio format standard as that used by an audio contents provider.

In operation 94, the wired audio output apparatus detects errors from the PCM data obtained in operation 93.

In operation 95, the wired audio output apparatus counts the number of error frames detected in operation 94 from frames that make up an error detection unit.

In operation 96, the wired audio output apparatus determines a volume level corresponding to a threshold range to which the value counted in operation 95 belongs with reference to the threshold table 57 in which error count thresholds and volume levels corresponding to each other are stored.

In operation 97, the wired audio output apparatus temporarily stores and outputs the PCM data obtained in operation 93 in order to match a data output speed of the audio output apparatus in the wired environment with a data processing speed of the device that processes data output from the audio output apparatus in the wired environment.

In operation 98, the wired audio output apparatus controls a volume of the PCM data output in operation 97 according to the volume level determined in operation 96.

In operation 99, the wired audio output apparatus converts the PCM data of operation 98 to a user-audible analog signal and outputs the user-audible analog signal to the speaker 511.

The exemplary embodiments described above may be produced by a computer readable program and, embodied in a general-purpose digital computer by running the program from a computer readable recording medium.

The computer readable medium includes but is not limited to storage media such as magnetic storage media (ROMs, RAMs, floppy disks, magnetic tapes, etc.), optically readable media (CD-ROMs, DVDs, etc.), and carrier waves (transmission over the Internet).

As described above, according to exemplary embodiments of the present invention, by controlling a volume of audio data based on the number of errors generated from the audio data, i.e., by reducing the volume when the number of errors is large and allowing the volume to be heard clearly when the number of errors is small, sound that is not unpleasant for listeners can be provided.

In particular, even in a situation in which a lot of noise is mixed with audio data when a transmission environment deteriorates suddenly, a method is provided so that a volume of harsh pop sound is automatically lowered even if the user does not control the volume manually. In addition, the user can listen to sound of suitable volume for a listening environment or the user's taste by setting threshold volume levels.

While this invention has been particularly shown and described with reference to exemplary embodiments thereof, it will be understood by those skilled in the art that various changes in form and details may be made therein without departing from the spirit and scope of the invention as defined by the appended claims. The above-described exemplary embodiments should be considered in a descriptive sense only and are not for purposes of limitation. Therefore, the scope of the invention is defined not by the detailed description of the invention but by the appended claims, and all differences within the scope will be construed as being included in the present invention.

What is claimed is:

1. A volume control method comprising:
detecting errors from data; and
controlling an output volume of the data based on a number of the errors which are detected.

2. The method of claim 1, wherein in the controlling of the output volume of the data based on the number of the errors, the output volume is controlled to be inversely proportional to the number of the errors.

3. The method of claim 1, wherein the data includes a plurality of frames forming audio contents, and
in the detecting of the errors from the data, the errors are error frames detected from the plurality of frames, and
in the controlling of the output volume of the data based on the number of the errors, the volume is controlled based on a number of the error frames.

4. The method of claim 3, further comprising:
counting the number of the error frames which are detected during a predetermined volume of frames, and
in the controlling of the output volume of the data based on the number of the errors, the volume is controlled based on the number of the error frames.

5. The method of claim 1, further comprising:
determining a volume level corresponding to a threshold range to which the number of the errors belongs with reference to a table in which error count thresholds and corresponding volume levels are stored, and
in the controlling of the volume of the output data based on the number of the errors, the volume of the data is controlled based on the volume level which is determined.

6. The method of claim 5, wherein each of the thresholds is user-determined.

7. The method of claim 5, wherein in the controlling of the output volume of the data based on the number of the errors, the output volume of the data is controlled by multiplying the magnitude of the data by the volume level which is determined.

8. A volume control apparatus comprising:
an error detector which detects errors from data; and
a volume controller which controls an output volume of the data based on a number of the errors.

9. The apparatus of claim 8, wherein the volume controller controls the output volume to be inversely proportional to the number of the errors.

10. The apparatus of claim 8, wherein the data includes a plurality of frames forming audio contents,
the error detector detects error frames from the plurality of frames, and
the volume controller controls the output volume based on a number of the error frames.

11. The apparatus of claim 10, further comprising:
a counter which counts the number of the error frames detected by the error detector during a predetermined volume of frames,
wherein the volume controller controls the volume based on the number of the error frames.

12. The apparatus of claim 8, further comprising:
a volume determiner which determines a volume level corresponding to a threshold range to which the number of the errors belongs with reference to a table in which error count thresholds and corresponding volume levels are stored,
wherein the volume controller controls the output volume of the data based on the volume level determined by the volume determiner.

13. The apparatus of claim 12, wherein each of the thresholds is user-determined.

14. The apparatus of claim 12, wherein the volume controller controls the output volume of the data by multiplying a magnitude of the data by the volume level determined by the volume determiner.

15. A computer readable recording medium having recorded thereon a computer readable program for performing a volume control method comprising:
detecting errors from data; and
controlling an output volume of the data based on a number of the errors which are detected.

16. A two-channel volume control method comprising:
detecting first channel error frames from a plurality of first channel frames and detecting second channel error frames from a plurality of second channel frames;
controlling an output volume of the first channel frames based on a number of the first channel error frames; and
controlling an output volume of the second channel frames based on a number of the second channel error frames.

17. A wireless signal volume control method comprising:
extracting a predetermined wireless signal from wireless signals;
demodulating the predetermined wireless signal which is extracted to generate a demodulated signal;
decoding the demodulated signal to generate decoded data;
detecting errors from the decoded data; and
controlling an output volume of the data based on a number of the errors which are detected.

18. A wired signal volume control method comprising:
receiving a wired signal from an external network;
extracting a predetermined bitstream from the wired signal which is received;
decoding the predetermined bitstream which extracted to generate decoded data;
detecting errors from the decoded data; and
controlling an output volume of the data based on a number of the errors which are detected.
